(19) United States
(12) Patent Application Publication
(10) Pub. No.: US 2026/0320381 A1
(43) Pub. Date: Oct. 15, 2026

(54) Methods for Data-Free Deep Neural Network (DNN) Model Compression

(71) Applicant: Intel Overseas Funding Corporations, Chandler, AZ (US)

(72) Inventors: Matan Haroush, Binyamina (IL); Itay Hubara, Haifa (IL); Elad Hoffer, Haifa (IL)

(73) Assignee: Intel Overseas Funding Corporations, Chandler, AZ (US)

(21) Appl. No.: 19/465,843

(22) Filed: Jan. 30, 2026

Related U.S. Application Data
(63) Continuation of application No. 17/088,625, filed on Nov. 4, 2020, now abandoned.
(60) Provisional application No. 62/931,836, filed on Nov. 7, 2019.

(51) Int. Cl. G06N 3/08; G06N 3/0495; H03M 7/30

(52) U.S. Cl. CPC G06N 3/08; G06N 3/0495; H03M 7/30

(57) ABSTRACT

A data-free model compression method includes uploading a pre-trained model to a processor. A trainable model is defined. Random data samples are inputted to the pretrained model and a loss function including a loss term is iteratively minimized to obtain a training data set, the loss term quantifying differences in batch normalization statistics (BNS) between activation statistics of the pretrained model and intermediate batch normalization statistics of the pretrained model. Using the training data set, the trainable model is compressed by minimizing a total loss between the trained trainable model and the pretrained model, to obtain a compressed topology of the trained model.

### CROSS-REFERENCE TO RELATED APPLICATIONS

This application is a continuation of (and claims the benefit of priority to) U.S. patent application Ser. No. 17/088,625, filed Nov. 4, 2020 and titled “METHODS FOR DATA-FREE DEEP NEURAL NETWORK (DNN) MODEL COMPRESSION,” which claims the benefit of priority to U.S. Provisional Patent Application 62/931,836, filed Nov. 7, 2019 and titled “METHOD FOR MEASURING DATA CORRESPONDENCE VIA PROXY FOR SYNTHETIC SAMPLE GENERATION USED IN CONJUNCTION WITH DATA FREE COMPRESSION OF NEURAL NETWORKS FOR INFERENCE ON ACCELERATOR HARDWARE AND APPLICATIONS FOR INTERNAL STATISTICS MONITORING,” each of which is incorporated herein by reference in its entirety for all purposes.

### FIELD OF THE INVENTION

The present invention relates generally to methods for performing deep learning, and particularly to approximate methods for calibrating and fine-tuning a neural network model.

### BACKGROUND OF THE INVENTION

Statistical methods for using and adjusting Artificial Neural Networks (ANN) models were previously proposed. For example, Lopes et al. proposed to, in “Data-free knowledge distillation (KD) for deep neural networks,” arXiv preprint arXiv:1710.07535, 2017, use data-free knowledge distillation for model compression by collecting metadata related to the statistics of a trained model output. In particular the authors proposed an approach to capture inter-layer relations via graph spectral analysis. However, this is impractical for large ANN models or ANN models with large input size, due to its computational cost.

As another example, Bhardwaj et al. suggested in, “A data-independent model compression framework,” arXiv preprint arXiv:1905.07072, 2019, that it is sufficient to collect metadata from the layer before a linear classifier. Metadata collection is done therein by processing a small portion of the training set, clustering the high dimensional outputs and applying Principle Component Analysis (PCA) per cluster. The optimization target is based on the collected centroids and a random noise projected in the direction of the primary principle components. However, relatively large degradation between real data to the generated samples was demonstrated therein.

Nayak et al. proposed in, “Zero-shot knowledge distillation in deep networks,” arXiv preprint arXiv:1905.08114, 2019, a data-free method dubbed as zero-shot distillation, which relies solely on the final layer weights to compute a class similarity matrix. Then, sample soft targets via Dirichlet distribution for generating synthetic images. However, KD results on synthetic samples are only comparable to real data on easily separable datasets.

### SUMMARY OF THE INVENTION

An embodiment of the present invention that is described hereinafter provides a data-free model compression method, the method including uploading a pretrained model to a processor. A trainable model is defined. Random data samples are inputted to the pretrained model and a loss function including a loss term is iteratively minimized to obtain a training data set, the loss term quantifying differences in batch normalization statistics (BNS) between activation statistics of the pretrained model and intermediate batch normalization statistics of the pretrained model. Using the training data set, the trainable model is compressed by minimizing a total loss between the trained trainable model and the pretrained model, to obtain a compressed topology of the trained model.

In some embodiments, defining the trainable model includes maintaining a same topology of the pretrained model and the trainable model.

In some embodiments, the loss term is a Kullback-Leibler (KL) loss.

In an embodiment, the total loss includes a Kullback-Leibler (KL) loss and an intermittent quantization (IQ) loss term.

In some embodiments, in at least one layer, the compressed topology differs from the pretrained topology in a number of neurons.

In some embodiments, the compressed topology differs from the pretrained topology in in weights accuracies. In other embodiments, the compressed topology differs from the pretrained topology in activation values accuracies.

In an embodiment, the differences in batch normalization statistics include differences in mean and standard deviation values of batch normalization probability distributions.

There is additionally provided, in accordance with another embodiment of the present invention, a data-free model compression method, the method including uploading a pretrained model having a given topology to a processor. A trainable model is defined. Random data samples are inputted to the pretrained model and to the trainable model and a loss function including a loss term is iteratively minimized to compress the trainable model by minimizing a total loss between the trained trainable model and the pretrained model, to obtain a compressed topology of the trained model.

In some embodiments, inputting the random data samples includes training a NN-generator to generate the random data samples and replacing inputs of one or more intermediate network layers by random data samples.

There is further provided, in accordance with another embodiment of the present invention, an apparatus for data-free model compression, the apparatus including an interface and a processor. The interface is configured to upload a pretrained model having a given topology to the processor. The processor is configured to (a) define a trainable model, (b) input random data samples to the pretrained model and iteratively minimize a loss function including a loss term, the loss term quantifying differences in batch normalization statistics (BNS) between activation statistics of the pretrained model and intermediate batch normalization statistics of the pretrained model, to obtain a training data set, and (c) using the training data set, compress the trainable model by minimizing a total loss between the trained trainable model and the pretrained model, to obtain a compressed topology of the trained model.

There is furthermore provided, in accordance with another embodiment of the present invention, an apparatus for data-free model compression, the apparatus including an interface and a processor. The interface is configured to upload a pretrained model having a given topology to the processor. The processor is configured to define a trainable model, and input random data samples to the pretrained model and to the trainable model and iteratively minimize a loss function including a loss term, to compress the trainable model by minimizing a total loss between the trained trainable model and the pretrained model, to obtain a compressed topology of the trained model.

The present invention will be more fully understood from the following detailed description of the embodiments thereof, taken together with the drawings in which:

### BRIEF DESCRIPTION OF THE DRAWINGS

FIG. 1 is a schematic, pictorial block diagram of an artificial neural network (ANN), in accordance with an embodiment of the present invention;

FIG. 2 is a block diagram schematically describing a compression process of the ANN of FIG. 1, in accordance with an embodiment of the present invention;

FIG. 3 is a block diagram schematically describing an iterative process of generating synthetic input samples mimicking the inter-model statistical properties of real samples and using these to compress the teacher artificial neural network (ANN) into a student ANN of FIG. 2, in accordance with the first embodiment of the present invention;

FIG. 4 is a flow chart schematically describing the iterative process of sample generation of FIG. 3, and subsequent compression of the teacher artificial neural network (ANN) into the student ANN of FIG. 2, in accordance with the first embodiment of the present invention;

FIG. 5 is a flow chart that schematically illustrates a method of data-free calibration of the student ANN model of FIG. 2, in accordance with the first embodiment of the present invention;

FIG. 6 is a flow chart that schematically illustrates a method of data-free fine-tuning the student ANN of FIG. 2, in accordance with the first embodiment of the present invention;

FIG. 7 is a block diagram, along with a flow chart schematically describing a method using random noise images for training and data-free disjoint random fine-tuning of a student artificial neural network (ANN), in accordance with the second embodiment of the present invention;

FIG. 8 is a flow chart that schematically illustrates the method of FIG. 7 with a refined data-free disjoint random fine-tuning, in accordance with the second embodiment of the present invention; and

FIG. 9 is a flow chart that schematically illustrates a method of data pruning in the teacher ANN of FIG. 2, in accordance with either the first or second embodiments of the present invention.

### DETAILED DESCRIPTION OF EMBODIMENTS

### Overview

Artificial Neural Networks (ANN) comprise a large number of simple neuron circuits (called hereinafter “nodes”), each of which performs an elementary non-linear transformation of multiple inputs it receives by applying an activation function to a weighed sum of the inputs. Acting collectively, the nodes can calculate accurate solutions to many complex problems, such as natural language processing and computer vision.

A neural network is considered a deep neural network if it has one or more “hidden layers” of nodes, each of which processes multiple inputs, and an output layer that provides the final output of the model. In a deep neural network, output values of the nodes propagate in a forward direction through the network from input to output layers, including through any number of the hidden layers between them.

Practical ANNs may include numerous hidden layers and nodes, which can make the ANN storage and computational cost limiting factors, especially for some real-time applications. In particular, a size of an ANN may limit its deployment in portable devices (e.g., augmented reality glasses) with limited resources (e.g., memory, CPU, energy, bandwidth).

A technique called “NN compression”, which falls under the general categories of “NN calibration” and “NN fine-tuning” algorithms, may be used to decrease a size of an ANN and/or a number of the parameters being used by the ANN, such as weights, while retaining in essence the performance of the original ANN. To reduce ANN size, NN compression may implement knowledge distillation (KD), in which a distribution of class probabilities predicted by a large size pretrained ANN (“teacher model”) is transferred from the teacher model to a smaller size ANN (“student model”) by minimizing a so-called distillation loss function.

Many NN compression algorithms require using part of a training dataset of the teacher model for the calibration or fine-tuning, including the ANN compression. However, this requirement is unacceptable when the training data is unavailable or contains sensitive information, as in medical and biometric use-cases. Attempts to save the need in a training dataset may include generating training samples (so called “data-free” approach). However, adjusting parameters of an ANN model by using distillation over such randomly generated training samples, irretrievably alters (e.g., causing divergence of) a statistical correction, known as “batch normalization (BN)” of the input and of hidden layers, to accommodate for the observed statistical properties, resulting in an imminent failure when applying the distillated NN to evaluate real data.

BN has been shown to improve both accuracy and speed of convergence of ANN models by normalizing an input to the layer to have zero mean and unit variance before applying its operation. During training, each BN layer keeps a running estimate of the empirical mean and standard-deviation of its inputs which latter applied to normalize the input data during inference.

Embodiments of the present invention that are described hereinafter provide methods and computational apparatuses for data-free compression by statistically constraining NN batch normalization. In the embodiments of the disclosed invention, the algorithm forces all BN layers in the NN model to maintain their original running estimates for evaluation. As shown below, this may enable the use of random samples (i.e., data-free approach) for the task of distillation.

Two embodiments are provided hereinafter, in which a processor data-freely generates the trained student ANN model having a compressed topology by compressing a pretrained teacher ANN having a pretrained topology: In a first embodiment, the processor first generates, using the teacher model, a training set of samples by minimizing BNS loss. Subsequently, the processor, using the set of samples, compresses the student model. In a second embodiment, which is also data-free, no training data set is generated by the processor. Instead, the student model is compressed using a generative model (comprising “NN generators”) to generate random samples with arbitrary disjoint training of the NN generator, as described below, to have a data set needed for compressing the student model. In both embodiments, an algorithm is provided, which provides a statistical loss term called, “batch normalization statistics (BNS),” that uses predetermined, estimated, statistics of BN layers of the teacher ANN model (e.g., mean and STDEV per layer) as an optimization target in the process of producing the samples, in the first embodiment, and training the NN generators, in the second embodiment.

The first embodiment comprises two stages. The first stage involves extracting the training data using the teacher model and a set of activations statistics, by iteratively minimizing a statistical similarity loss such as BNS, which is based on the KL divergence for isotropic gaussian distribution. The reference statistics can be extracted directly from the teacher's BN layers, or provided independently (e.g. by the owner of the teacher network). The second stage deals with training the student topology using the teacher and the synthetic data, based on classic KD methods with a few modifications (i.e., IQ loss, disjoint training).

During the preliminary stage of extracting the training data, deriving BNS loss with respect to the teacher's (arbitrarily initialized) inputs, can be used to produce a fixed set of training examples. Alternatively, it is possible to train an NN-generator by deriving BNS with respect to the generator parameters (e.g., learning to imitate the training dataset distribution). The synthetic data used for the teacher compression in the second stage is either drawn from a finite set of samples, or from a generative model. Thus, when training the student network using the synthetic inputs and KD loss on the final layer of the teacher, the first and second embodiments conceptually converge (i.e., when considering the entire teacher network as a single functional block).

In the first embodiment, thus, the algorithm iteratively generates a set of random input samples, where in the iterative process, these samples are adjusted by minimizing a statistics loss function comprising statistical properties differences (e.g., of mean and STDEV) between the BN statistics of the original (i.e., pretrained) teacher ANN model and that generated by the teacher model using the disclosed BNS algorithm. The resulting set of training samples of the iterative process is used, by minimizing a total loss defined below, to compress a trainable model, which can be a model with a same topology as the teacher's model, but can be an arbitrary model, in principle, into a student model having a compressed topology. The generated set of training samples is no longer required then, but may found other use, such as to supplement new samples to reduce the cost of generating a full set from scratch. The data can be reused in continuous train-deploy cycles or for models that are trained on similar or identical datasets.

The second embodiment allows for samples to be drawn from a prior distribution based on the provided statistics (e.g., Gaussian distribution with mean and variance, taken from the batch normalization layers). This alleviates the need to perform the first step of the process of the first embodiment, which can be expensive and time consuming. Additionally, learning to imitate the entire training distribution based on the teacher network can be difficult. Thus, replacing the inputs at each functional block is appealing to avoid accumulating distributional bias as well as reducing the reliance on a single high-quality input source. This can be done by training individual block generators to replace the inputs of the last layer. An alternative example is to train the sequential generators to accommodate for the distribution shift by learning to transform the outputs of the previous layer (e.g., via a linear transformation), instead of replacing them altogether. The latter approach aims to deal with modelling the input distribution of the final block of the network where BNS information contribution is limited (due to the small number of layers). In the second embodiment, thus, the technique uses random data to train the predefined trainable student model. In an embodiment, during forward pass—random inputs (e.g., having Gaussian statistics) are fed to the distillated ANN model (i.e., to the student model under preparation). Then, for each layer, the processor computes KD loss independently. The next layer inputs are replaced with fresh random samples using the ultimate BN layer of the current layer's reference statistics (running mean, STDEV). In other words, the method truncates the distillated ANN model to disjoint intervals between BN layers, and then retrains, and then retrains the student model with the random samples. In one example of the second embodiment, Gaussian samples are used and the synthetic data is generated by the applying Gaussian scheme on the statistics of the previous BN layer.

The second embodiment allows to replace the inputs at arbitrary network layers with synthetic data from dedicated generators (i.e., isotropic Gaussian based on running mean and variance or the NN generators after they are trained to using BNS). For example, NN-Generators are used, which are simple generative models implemented using small NNs. The goal of the generator is to produce random data that maintains BNS loss for the proceeding layers in the network from a certain intermediate layer and on.

In the second embodiment, a set of generators are trained using the same procedure used for producing synthetic samples directly. However, instead of deriving the BNS loss with respect to the input we derive it with respect to the generator parameters. This approach aims to avoid accumulated deterioration of statistic preserving qualities of the synthetic data as it propagates through the network.

The disclosed technique is exemplified using as the teacher model an ANN model using floating-point numbers, and as the student model its quantized variant. Specifically, a processor applies the most demanding configuration from the previous calibration experiment (e.g., in a sense of a distance 11) to create the student model from the teacher model, as described below. Otherwise the teacher and student models are kept the same, with (a) teacher predictions used as targets without additional labels, and (b) the teacher and student ANN sharing a same architecture (e.g., both NNs having same number of hidden layers and nodes per layer).

In some embodiments, thus, an additional loss optimization is used with the aforementioned teacher-student model, under the assumption that a good low precision proxy exists within the vicinity of a reference model in the parameters space. Specifically, intermediate layer outputs are used to compute a smoothed distance (e.g., |1) between the teacher and the student features, this loss named hereafter Intermediate Quantization (IQ) loss. The inventors have found IQ generally lead to a more stable training convergence under extreme quantization and improve KD results for both synthetic and real samples.

While the description is focused on leveraging Batch Normalization Layers within the models by the BNS method described above, other methods may be used. Given appropriate reference low-order statistics (e.g., a set of mean and covariance matching to some or all of the teacher's layers), an arbitrary differentiable (or approximately differentiable) divergence measure can be used instead. For instance, given mean and variance of an arbitrary set of layers (other than BN layers—which may not exist in some models), any LP distance can be used as a simplistic divergence metric over the observed mean and variance to produce the synthetic data.

By providing original-data-free or true-data-free KD techniques, artificial intelligence products using the disclosed methods and computational apparatuses could achieve wider commercial use.

### System Description

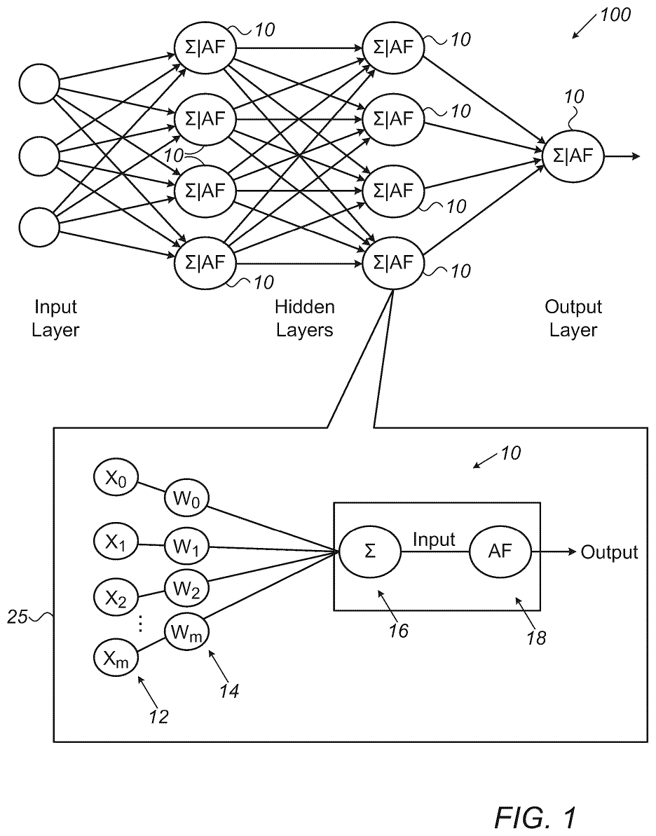

FIG. 1 is a schematic, pictorial block diagram of an artificial neural network (ANN) 100, in accordance with an embodiment of the present invention. ANN 100 is a simplified deep neural network brought purely for clarity and simplicity of presentation. In ANN 100, each node 10 is connected to numerous other nodes, allowing signals to pass, e.g., during inference or during training, in a forward direction through the network from input to output layers through the hidden intermediate layers.

Typically, forward propagation is the process of multiplying the various input values of a particular node 10 by their associated weights, summing the results, and non-linearly scaling the output values using an activation function (AF) 18 to fall in a predetermined range. The signals are then passed on to the next layer of nodes.

Forward propagation performed by an example node 10 is illustrated in inset 25, where the input to an AF 18 is a sum 16 of products of inputs {Xₖ} 12 and their corresponding weights {Wₖ} 14. When a layer is batch-normalized, the layer's vector {Xₖ} 12 has a zero mean value and a unit STDEV.

A normalized output (i.e., {Xₖ}) of a BN layer of nodes 10 is fed as an input to the next layer. This, in turn, affects the weighted input value sums of the following layers of ANN 100, and so on, which then affects the computation of new weights and their distribution backward through the network. Ultimately, the above-described process affects the final output value(s) of ANN 100.

The different elements of ANN 100 may be implemented using suitable hardware, such as in one or more Application-Specific Integrated Circuits (ASICs) or Field-Programmable Gate Arrays (FPGAs), using software, using hardware, or using a combination of hardware and software elements.

In some embodiments, some or all of the functions of ANN 100 may be implemented in a general-purpose processor, which is programmed in software to carry out the functions described herein. The software may be downloaded to the processor in electronic form, over a network, for example, or it may, alternatively or additionally, be provided and/or stored on non-transitory tangible media, such as magnetic, optical, or electronic memory.

### Artificial Neural Network (NN) Compression Scheme

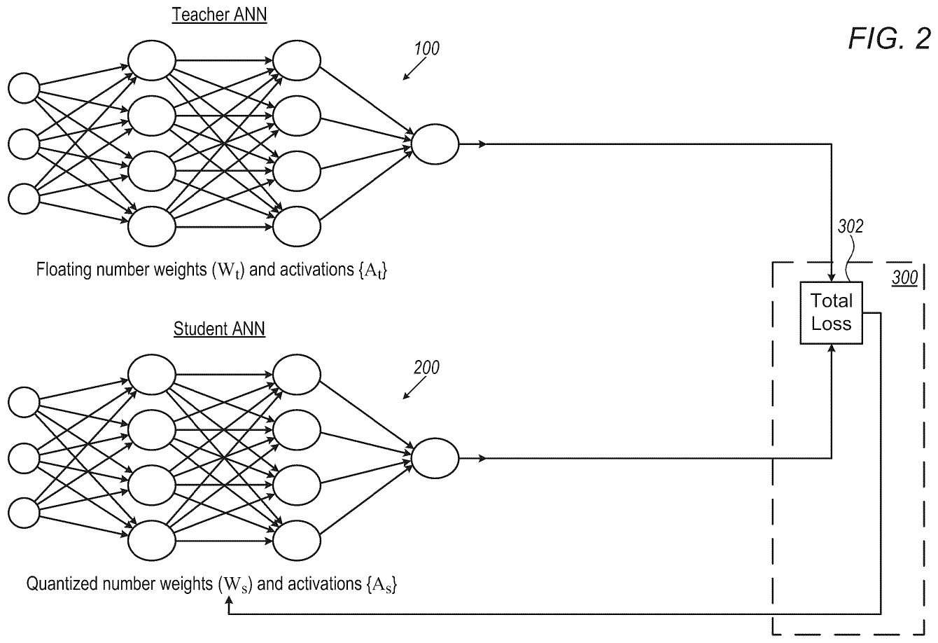

FIG. 2 is a block diagram schematically describing a compression process of ANN 100 of FIG. 1, in accordance with an embodiment of the present invention. In FIG. 2, ANN 100 represents a full precision, e.g., floating point, model (or parts of it) and serves as the pretrained teacher ANN model, while the student ANN 200 is the low precision counterpart. As seen, the teacher and student networks have a same structure (e.g., topology).

In the shown embodiment teacher ANN 100 of FIG. 1 has real number valued weights {Wₜ} and activation output values {Aₜ}, provided as floating numbers. However, using floating numbers such way in large ANNs is computation and memory consuming. The disclosed NN compression process generates a quantized variant ANN 200 of ANN 100, where ANN 200 uses quantized weights {Wₛ} and activations {Aₛ}. For example, the discrete (also called “quantized”) values can be represented using an 8-bit dynamic range. To best-approximate the real number values with the discrete ones, a knowledge distillation loop 300 minimizes a total-loss difference function 302.

The disclosed technique takes advantage of the shared teacher and student ANN model structure, and applies a simple approximation scheme, under the assumption that a good low precision proxy exists within the vicinity of the reference model in the parameters space. Specifically, the algorithm uses intermediate layer outputs to compute the smoothed 11 distance between the teacher and the student features (e.g., weights and activation values), this loss named hereinafter as “Intermediate Quantization (IQ) loss.” As shown, using IQ loss generally leads to a more stable training convergence under extreme quantization and improve KD results for both synthetic and real samples.

Formally,

$${loss}_{IQ} = {\sum }_{{l}_{i} ∈ L} {criterion}_{IQ} ( {aux}_{t}^{{l}_{i}} , {aux}_{s}^{{l}_{i}} ) \qquad Eq . 1$$

where loss IQ is a sum of auxiliary losses of the teacher and student networks.

IQ loss is applied between matching pairs of teacher and trainable student layers, and the matching can be heuristic or exact. Most basically, IQ loss can only be applied to layers with the same dimensions (i.e. number of channels, high & width). However, it can also apply to different network shapes via auxiliary learnable/fixed linear transformation. In this case, the transformation is applied to the student features before computing the IQ loss and are discarded at the end of training (as they are not part of the final model).

IQ injects additional information regarding the teacher internal embeddings for the given inputs. The purpose is to synchronize the student & teachers embeddings (as opposed to only using the final outputs), this aims to limit the search space and retain the generalization qualities of the teacher (in the student model). In addition, adding auxiliary losses speeds up convergence. Eq. 1 derived in detail in Algorithm 2 in the paper, “The Knowledge Within: Methods for Data-Free Model Compression,” arXiv:1912.01274v2 dated Apr. 6, 2020, by Haroush et al., which is incorporated herein by reference.

To generate student ANN model 200, the processor minimizes a total-loss (302) given by

lossₜₒₜₐₗ=loss_{IQ}+loss_{KD}. Eq. 2

In Eq. 2, the disclosed KD loss function, loss_{KD}, is a Kullback-Leibler (KL) divergence-based statistics loss given in Eq. 3 below. The total loss of Eq. 2 is given by way of example, where total loss may include additional terms, such as regularization loss.

The teacher and student networks of FIG. 2 are brought purely by way of example, for clarity of presentation. In the portrayed case (unlike classic KD), the general student architecture (i.e. layer composition) remains the same while the weights and activations are quantized (represented with fewer bits)—hence smaller. In general, other compression methods are possible (e.g. pruning or architecture changes) by following a similar loss minimization scheme comprising KD loss minimization.

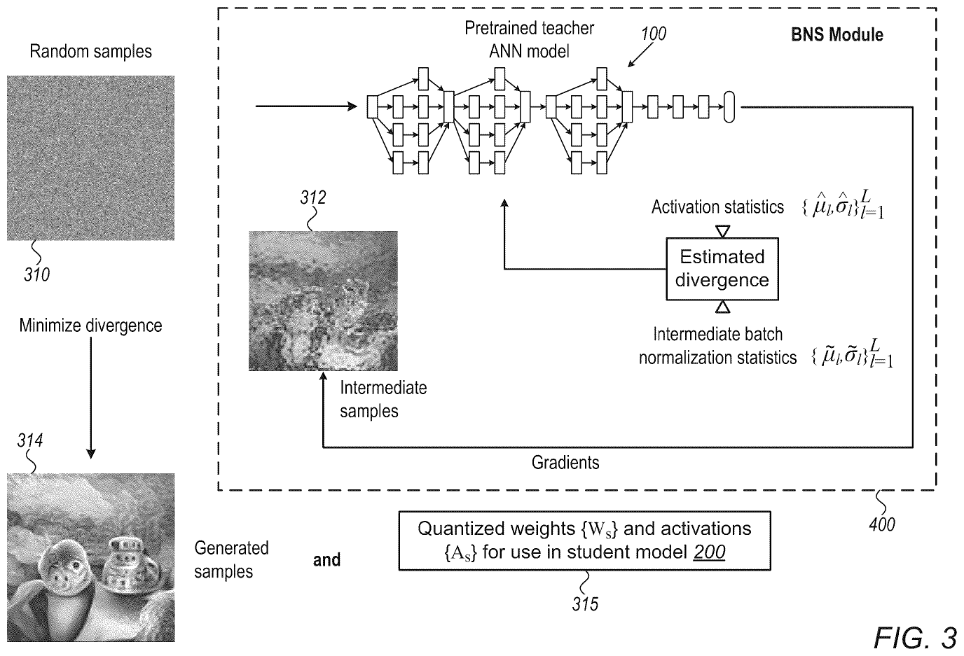

As noted above, in some cases a training data set (e.g., images) required to perform the compression process of FIG. 2 is unavailable. In the first embodiment, the disclosed technique is able to perform the KD process by first generating such data set based only on statistical properties of the teacher ANN (e.g., of ANN 100), using the below disclosed loss_{KD} as shown in FIG. 3.

### Batch-Normalization-Statistics (BNS) Scheme Including Generating Training Samples

As noted above, sample generation process may result in significant internal statistics divergence of NN values (e.g., weights, activations) from the observed (e.g., predetermined) statistics of a teacher ANN model on real data. Indicating such data-free generated samples are not drawn from a distribution similar to the original training data. This, in turn, may impede their use for model compression and KD. The disclosed approach therefore aims at directly minimizing the internal statistics divergence, by optimizing a novel measure which is termed hereinafter “BN-Statistics” (denoted as BNS). BNS only assumes access to the predetermined empirical measurements that occur for each BN layer of the teacher ANN model. These estimates as are used as targets and the disclosed technique compares new data samples by the similarity between their measured statistics.

FIG. 3 is a block diagram schematically describing an iterative process of generating synthetic input samples mimicking the inter-model statistical properties of real samples and using these to compress a teacher artificial neural network (ANN) 100 into a student ANN 200 of FIG. 2, in accordance with the first embodiment of the present invention.

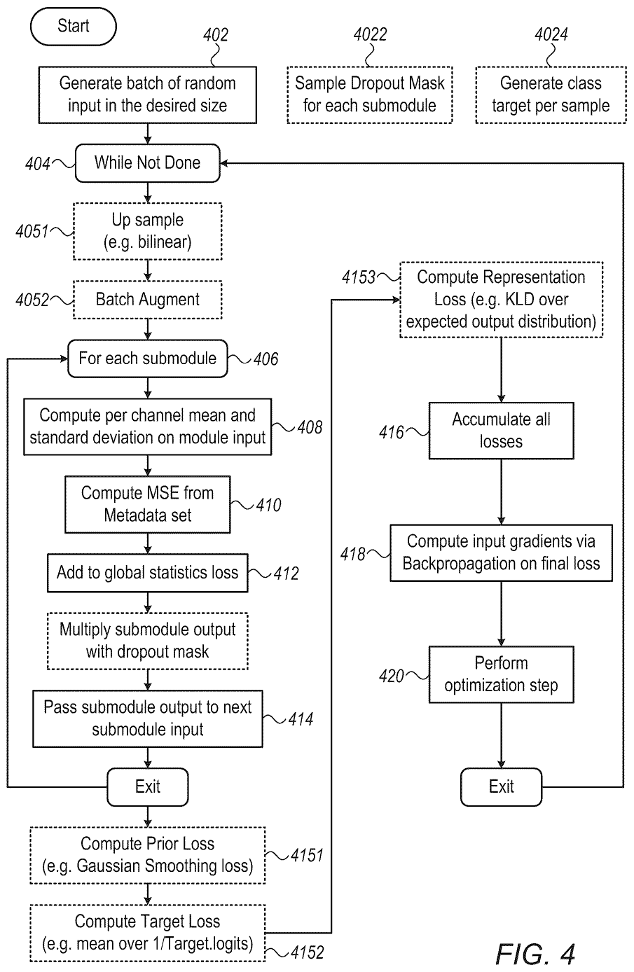

To this end, the synthetic input generation process uses statistical properties of ANN 100. A flow chart describing the method is given in FIG. 4.

As seen in FIG. 3, in lack of real samples (e.g., training data set being unviable), the disclosed technique uses a random data input samples 310 as initial samples. Using BNS module 400, described below, a processor is able to generate samples 314, which mimic the inter-model statistical properties of real samples, and subsequently, using samples 314, generate the derived parameters 315 for the student model (e.g., the quantized weights and activation values). The process of samples 314 generation is iterative, and an in intermediate iterations, the processor generates intermediate samples 312, which, as seen, could poses already in the very few first iterations some similarities to the final generated training samples 314.

As noted above, the disclosed data samples generation algorithm uses a batch normalization statistics (BNS) algorithm, and uses predetermined estimated statistics (e.g., mean and STDEV) of BN layers of ANN 100 as an optimization target. The algorithm iteratively generates a set of random input samples with these samples being adjusted by minimizing a statistics loss function comprising statistical properties differences (e.g., in mean and STDEV) between the original BN statistics obtained by using the unviable training set and that generated by the disclosed algorithm.

More formally, as shown in BNS module 400 and as described in the flow chart of FIG. 4, given the running estimates \hat{μ} and \hat{σ} of a given batch-norm layer, the disclosed BNS algorithm aims at measuring \tilde{μ}=μ(D) and \tilde{σ}=σ(D) of new data activations D (also called hereinafter, “Intermediate batch normalization statistics”) and evaluate their similarity to the reference statistics (i.e., to original estimates of \hat{μ} and \hat{σ} per any intimidate layer of the teacher model, also called hereinafter, “activation statistics”). BNS defines this similarity using the Kullback-Leibler (KL) divergence under a simplistic isotropic Gaussian assumption such that

$$BNS ( D , \hat{μ} , \hat{σ} ) = KL ( N ( \hat{μ} , {\hat{σ}}^{2} ) ‖ N ( \tilde{μ} , {\tilde{σ}}^{2} ) ) = log \frac{\tilde{σ}}{\hat{σ}} - \frac{1}{2} ( 1 - \frac{{\hat{σ}}^{2} - {( \hat{μ} - \tilde{μ} )}^{2}}{{\tilde{σ}}^{2}} )$$

The sample generation process starts with a batch of random input samples 310, which are then iteratively adjusted to minimize the mean statistical divergence across all layers in the reference set. Namely, for each optimization step over an input batch X, a processor extracts a per-BN-layer activation set

$${\{ {D}_{l} \}}_{l = 1}^{N} .$$

An optimization objective is then defined as the mean statistics' divergence over all BNS(Dₗ, μₗ, \hat{σ}ₗ). Formally, the first and second moments sets are defined as:

T,S:={Pₗ~N(\hat{μ}ₗ,\hat{σ}ₗ)}ₜ₌₁^{N},{Qₗ~N(\tilde{μ}ₗ,\tilde{σ}ₗ)}ₜ₌₁^{N} Eq. 4

while the optimization objective (i.e., BNS measure) is defined as the mean KL divergence on the set {T,S}, i.e.

$${J}_{KL} ( X \vert T , S ) := \frac{1}{N} {\sum }_{l = 1}^{N} KL ( {P}_{l} ‖ {Q}_{l} ) = \frac{1}{N} {\sum }_{l = 1}^{N} BNS ( D , \hat{μ} , \hat{σ} ) \qquad Eq . 5$$

A small ε=1e⁻⁸, is added to the measured variance of the induced synthetic distribution to accommodate for zero-variance channels. It noted that alternative metrics can be used for BNS under the same underlying assumptions, such as Mean Square Error over the empirical moments which is symmetric and can handle zero variance channels. Finally, standard backpropagation is used to adjust X.

The set of training samples 314 can be further used, for example, for training other models that require a similar unviable training data set, to replace the unviable training set for training, to perform calibration and/or fine-tuning, including compressing another teacher ANN. The later use is possible if the original training data is similar enough (or identical) this can be determined by examining BNS loss values with the new model. Preferably, however, a new set would be generated, while older set of samples can be used to increase the number of datapoints.

### Method of Sample Generation

FIG. 4 is a flow chart schematically describing the iterative process of sample generation of FIG. 3, and subsequent compression of teacher artificial neural network (ANN) 100 into the student ANN 200 of FIG. 2, in accordance with the first embodiment of the present invention. Steps 402-414 of the flow chart describe running the teacher model to generate a set of training samples 314 using BNS loss calculated between the outputs of pretrained model 100 and outputs of model 100 during training. Steps 416-420 describe subsequent steps, in which a student model (i.e., ANN 200) is derived, using the training samples, by minimizing a total loss between the pretrained teacher model and a trainable model, as shown, by way of example, in FIG. 2.

The shown flow chart is of a non-limiting example implementation for the generation method and tailored data-free compression method, that is optimized for accelerator hardware. In FIG. 4, each block describes linear steps for the specific method, while broken blocks denotes optional steps.

For simplicity FIG. 4 describes an algorithm to produce a batch of samples and refer to a set of meta data which describes channel-wise mean and standard deviation per layer of the model. This information can be directly inferred from batch normalization layers, commonly used in modern architectures of neural networks resulting in an entirely data independent method (Data-Free) approach which requires no additional prior knowledge on the training data other than the trained model itself.

The algorithm, according to the present embodiment, carries out a process that begins with a processor that implements ANN 100 generating a batch of random input X₀ of a required size, such as a batch of random-data images 310, at a step 404. The algorithm requires an ANN model with frozen parameters, a set of meta data with layer-wise index, and a fixed fix output target Y.

Next, while not done, the processor performs step 406-420, in which the processor performs the required optimization to produces training samples 314 and student ANN 200 parameters 315.

In particular, the processor runs forward pass with input Xᵢ, and retrieves Ŷᵢ and the matching set [symbol] collected during forward pass, at a statistics computing step 408.

Next, the processor computes target-loss (Y, Ŷᵢ) and stats-loss ({ [symbol] }, { [symbol] }), at a loss computation steps 410-412.

At a backpropagation step 418, the processor computes gradients on joint objective and updates Xᵢ₊₁.

The processor repeats steps 406-420 until objective converges.

Principle extensions (shown in broken blocks denoting optional steps) include:

Step 4151: Improving synthetic feature reproduction quality by using additional domain specific knowledge to configure optimization objective (e.g. compute smoothness-loss and/or continuity-loss on Xᵢ in addition to proposed base objective).

Step 4051: Improve sample generation speed and quality by generating smaller size input and interpolate to the original input size resulting in local gradient aggregation per sample.

Step 4052: Improve samples generation speed and quality by using in-batch augmentations; i.e. each input sample is duplicated several times with some augmentation policy resulting in gradient aggregation per sample.

Steps 4022 and 4024: Increase cross-sample variance by suppressing a fixed subsets of model features per sample, following logic of commonly used dropout layer where feature suppression is used both as a regularization mechanism and to encourage learning diverse features. In step 4022: For each input sample, generate an additional feature suppression mask (i.e. zero out the selected features for the entire duration of the feature reconstruction iteration of that sample). Suppression mask generation is independent of the target feature set which its magnitude is typically maximized by the target objective, while the probability of a neuron suppression can depend on previously observed statistics.

### Calibration and Fine-Tuning Using the Disclosed Technique

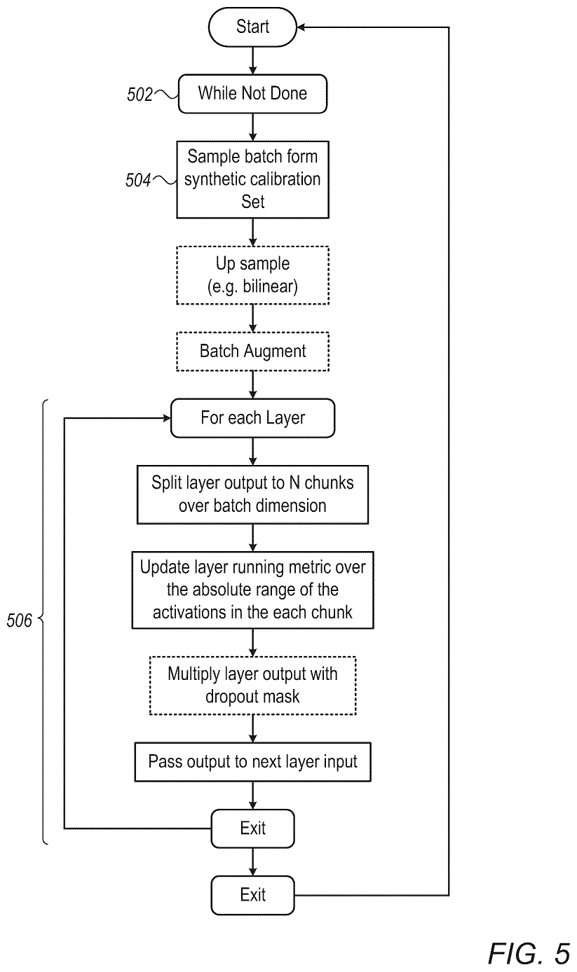

FIG. 5 is a flow chart that schematically illustrates a method of data-free calibration of student ANN model 200 of FIG. 2, in accordance with the first embodiment of the present invention.

In FIG. 5, each block describes linear steps for the specific method, while broken blocks denotes optional steps.

The algorithm, according to the present embodiment, carries out a process that begins with the processor sampling a batch from the synthetic calibration set 314, at a sampling step 504.

Steps of loop 506 carry the calculations of an update layer running metric and forward passing the updated metric from each layer into a next one until the end layer (where the metric minimized to obtain an optimized set of ANN 200 model parameters 315). Specifically, the metric in FIG. 5 I used for selecting proper dynamic range. However, other methods may be used. For instance, the range can be selected by approximating the 0.01 and 0.99 quantiles based on the distribution of the layer activations (for each layer/per-channel).

Additionally, splitting the batch dimension to N chunks is optionally used to increase device utilization by processing larger amounts of data in parallel (alternatively a smaller batch size can be used), also not a part of the patent claims.

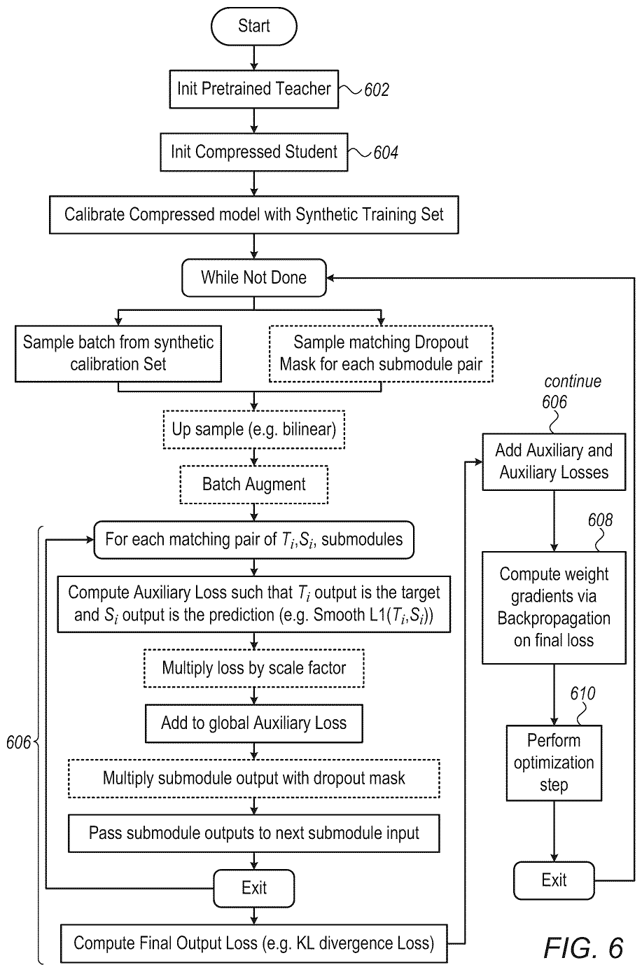

FIG. 6 is a flow chart that schematically illustrates a method of data-free fine-tuning student ANN 200 of FIG. 2, in accordance with the first embodiment of the present invention.

In FIG. 6, each block describes linear steps for the specific method, while broken blocks denotes optional steps.

The algorithm, according to the present embodiment, carries out a process that begins with the processor initiating pretrained teacher ANN model 100 and student ANN model 200 (e.g., by defining a trainable model as the zero iteration of student ANN model 200), at ANN models initiation steps 602 and 604, respectively.

Under step 606 of loss calculation, the processor performs calculation steps, including calculating Eqs. 1-5, to calculate a total loss function.

Next, at a backpropagation step 408, the processor computes from the total-loss function weights gradients.

During the iterative process, the processor optimizes (610) the weights to eventually derive a set of weights that minimizes the loss function (e.g., according to a predefined minimum criterion). At this point the process ends.

### Random Generators and NN-Generators Approaches

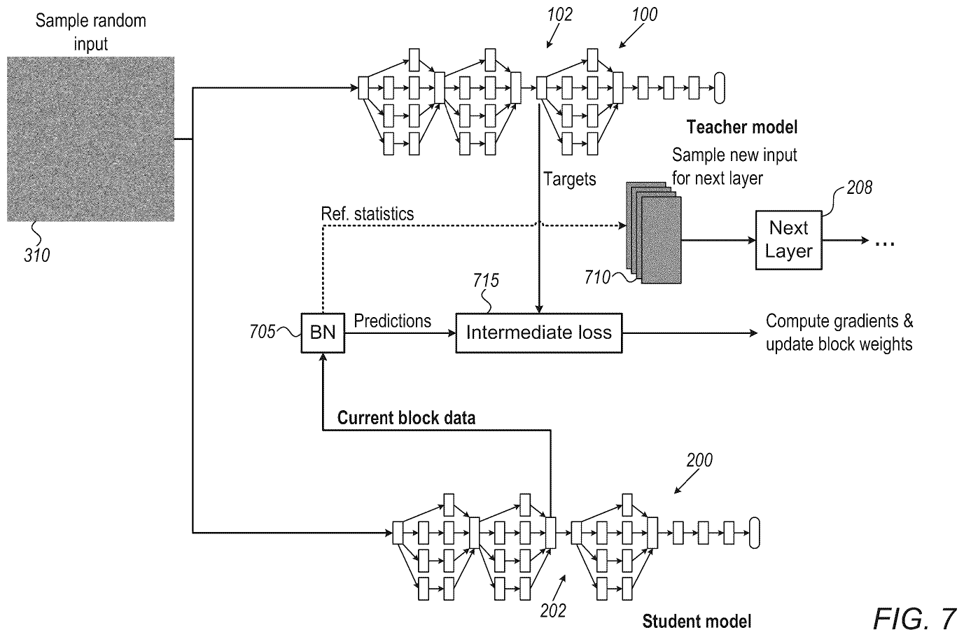

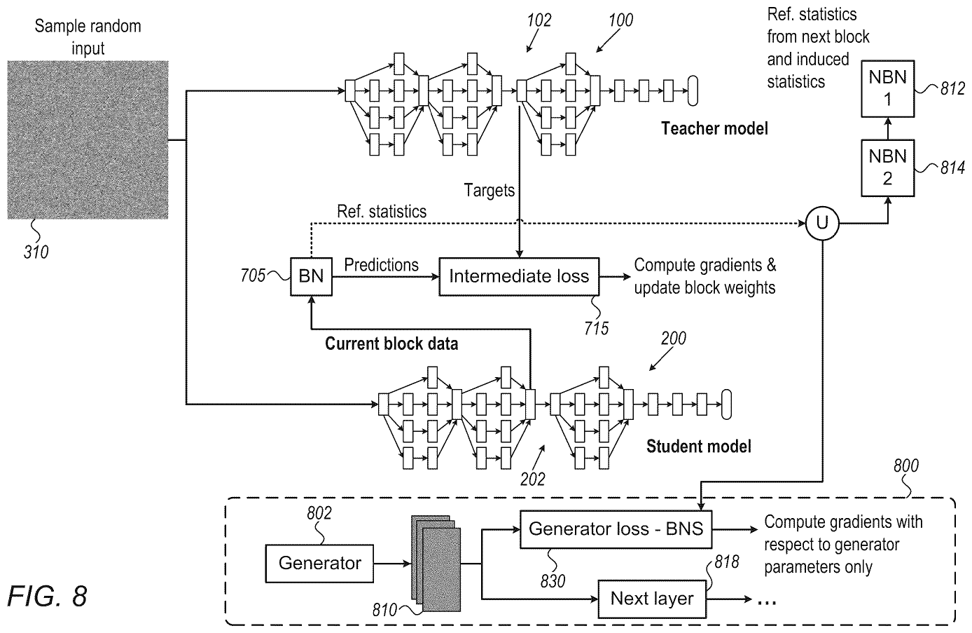

In contrast to the above approach of training the student model by inputting synthetic inputs to the first layer and have them propagated thought the rest of the network (to derive a training data set using ANN model 100), the methods described below in FIGS. 7 and 8 allow to replace the inputs at arbitrary network layers with synthetic data from dedicated generators (i.e. isotropic gaussian based on running mean and var or the NN generators after they are trained to using BNS).

The random input approach (FIG. 7) cannot represent higher order properties of the original signals (e.g. covariance or higher order moments) as this may hurt the quality of the tuned student.

The NN-Generators (FIG. 8) are simple generative models implemented using small NNs. The goal of the generator is to produce random data that maintains BNS loss for the proceeding layers in the network from a certain intermediate layer and on.

A set of generators are trained using the same procedure used for producing synthetic samples directly, however, instead of deriving the BNS loss with respect to the input we derive it with respect to the generator parameters.

The described approach aims to avoid accumulated deterioration of statistic preserving qualities of the synthetic data as it propagates through the network. Additionally, using NN generator serves as an intermediate alternative between training using randomized inputs and training with generated samples (ideally able to produce better quality students compared to the first while potentially faster process than the second).

FIG. 7 is a block diagram, along with a flow chart schematically describing a method using random noise images for training and data-free disjoint random fine-tuning of a student artificial neural network (ANN), in accordance with the second embodiment of the present invention.

To this end, the synthetic input generation process uses statistical properties of ANN 100. The disclosed disjoint training with random data does not require the processing and memory resources used in the data generation phase, such as in FIG. 3 to produce set of images 314.

As seen in FIG. 7, in lack of real samples (e.g., training data set being unviable), the disclosed technique uses (same as with FIG. 3) random input samples 310 as initial samples.

As seen, the pretrained teacher ANN model 100 and the student ANN models are used in parallel, for example, at processing BN layers 102 and 202. During forward pass—random inputs (310) are fed to both models (same as using isotropic Gaussian noise as input, with the activations propagate through the entire the network), then for each block the processor computes (715) KD loss independently. The next block inputs are replaced with fresh random samples 710 (e.g., Gaussian samples) using the ultimate BN layer of the current block's reference statistics (running average and STDEV). This is done to avoid building extensive distribution shift along the model (e.g., when going forward to layer 208) which occurs in the naive G method (i.e., each block is trained with samples 710 that are a zero-order approximation to the expected statistics).

FIG. 8 is a flow chart that schematically illustrates the method of FIG. 7 with a refined data-free disjoint random fine-tuning, in accordance with the second embodiment of the present invention.

The disclosed refinement aims at solving a problem that using Gaussian samples may cause losing ability to capture input signal complexity (i.e. spatial correlation).

The disclosed method adds more layers within each block (i.e., samples (810) generator 802, loss-BNS generator 830.

Use learnable distribution function (Generator) for the next block input (each generator takes in the current layer stat and learns, using a neuron by neuron (NBN) trainer algorithm to produce statistical preserving inputs from NBN blocks 812-814 for the next block 818).

### Compressing by Pruning Using the Disclosed Techniques

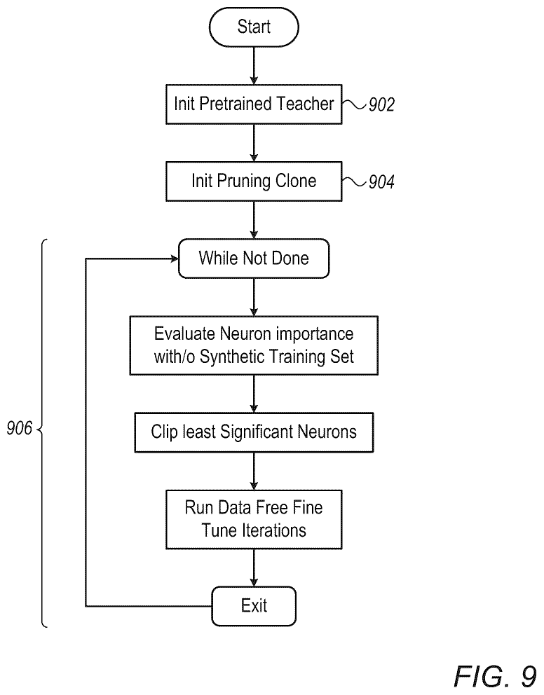

FIG. 9 is a flow chart that schematically illustrates a method of data pruning in teacher ANN model 100 of FIG. 2, in accordance with either the first or second embodiments of the present invention.

The algorithm, according to the present embodiment, carries out a process that begins with the processor initiating pretrained teacher ANN model 100, at ANN model initiation step 902. Next, the processor initiates pruning clone (with less neurons per layers, to adjust student ANN model 200), at pruning clone initiation step 904.

Under iterative step 906 of neuron pruning, the processor evaluates neuron contributions and clips insignificant neurons, until a predefined criterion is met (e.g., no neuron output is below threshold).

At this point the process ends.

Although the embodiments described herein mainly address deep learning applications, the methods described herein can also be applied to any other parametric models where the gradients with respect to the input can be calculated or indirectly approximated (e.g. using REINFORCE variants), given that a set of reference statistics are for intermediate representations are available.

It will thus be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. One or more non-transitory computer-readable media storing instructions executable to perform operations for generating a neural network model, the operations comprising:
generating an output of a teacher neural network model through a forward pass of the input sample through layers of the teacher neural network model, the layers comprising a batch normalization layer;
measuring one or more statistics of activations generated at the batch normalization layer during the forward pass;
generating a synthetic sample by adjusting the input sample based on the one or more measured statistics;
compressing the teacher neural network model to generate a student neural network model; and
training the student neural network model by using the synthetic sample as a training sample.

2. The one or more non-transitory computer-readable media of claim 1, wherein adjusting the input sample comprises:
adjusting the input sample to minimize a difference between the one or more measured statistics and one or more reference statistics of the batch normalization layer.

3. The one or more non-transitory computer-readable media of claim 2, wherein the input sample is adjusted further based on a difference between the output of the teacher neural network model and an output target of the teacher neural network model.

4. The one or more non-transitory computer-readable media of claim 3, wherein adjusting the input sample further comprises:
computing a loss based on the difference between the one or more measured statistics and the one or more reference statistics and the difference between the output and the output target;
performing a backward pass through the layers of the teacher neural network model based on the loss;
computing an input gradient through the backward pass; and
adjusting the input sample based on the input gradient.

5. The one or more non-transitory computer-readable media of claim 1, wherein the one or more measured statistics comprises a per-channel mean or a per-channels standard deviation of the activations generated at the batch normalization layer during the forward pass.

6. The one or more non-transitory computer-readable media of claim 1, wherein compressing the teacher neural network model comprises:
removing one or more neurons from the teacher neural network model,
wherein the one or more neurons are determined to be less important than one or more other neurons in the teacher neural network model.

7. The one or more non-transitory computer-readable media of claim 1, wherein compressing the teacher neural network model comprises:
quantizing weights of the teacher neural network model, wherein the weights of the teacher neural network model are predetermined through a training process.

8. The one or more non-transitory computer-readable media of claim 1, wherein the student neural network model has the layers of the teacher neural network model.

9. The one or more non-transitory computer-readable media of claim 1, wherein the operations further comprise:
calibrating the student neural network model before training the student neural network model.

10. A method for generating a neural network model, the method comprising:
generating an output of a teacher neural network model through a forward pass of the input sample through layers of the teacher neural network model, the layers comprising a batch normalization layer;
measuring one or more statistics of activations generated at the batch normalization layer during the forward pass;
generating a synthetic sample by adjusting the input sample based on the one or more measured statistics;
compressing the teacher neural network model to generate a student neural network model; and
training the student neural network model by using the synthetic sample as a training sample.

11. The method of claim 10, wherein adjusting the input sample comprises:
adjusting the input sample to minimize a difference between the one or more measured statistics and one or more reference statistics of the batch normalization layer.

12. The method of claim 11, wherein the input sample is adjusted further based on a difference between the output of the teacher neural network model and an output target of the teacher neural network model.

13. The method of claim 12, wherein adjusting the input sample further comprises:
computing a loss based on the difference between the one or more measured statistics and the one or more reference statistics and the difference between the output and the output target;
performing a backward pass of the teacher neural network model based on the loss;
computing an input gradient through the backward pass; and
adjusting the input sample based on the input gradient.

14. The method of claim 10, wherein the one or more measured statistics comprises a per-channel mean or a per-channels standard deviation of the activations generated at the batch normalization layer during the forward pass.

15. The method of claim 10, wherein compressing the teacher neural network model comprises:
removing one or more neurons from the teacher neural network model,
wherein the one or more neurons are determined to be less important than one or more other neurons in the teacher neural network model.

16. The method of claim 10, wherein compressing the teacher neural network model comprises:
quantizing weights of the teacher neural network model, wherein the weights of the teacher neural network model are predetermined through a training process.

17. The method of claim 10, further comprising:
calibrating the student neural network model before training the student neural network model.

18. An apparatus, comprising:
a computer processor for executing computer program instructions; and
a non-transitory computer-readable memory storing computer program instructions executable by the computer processor to perform operations for generating a neural network model, the operations comprising:
generating an output of a teacher neural network model through a forward pass of the input sample through layers of the teacher neural network model, the layers comprising a batch normalization layer,
measuring one or more statistics of activations generated at the batch normalization layer during the forward pass,
generating a synthetic sample by adjusting the input sample based on the one or more measured statistics,
compressing the teacher neural network model to generate a student neural network model, and
training the student neural network model by using the synthetic sample as a training sample.

19. The apparatus of claim 18, wherein adjusting the input sample comprises:
computing a first loss indicating a difference between the one or more measured statistics and one or more reference statistics of the batch normalization layer;
computing a second loss indicating a difference between the output of the teacher neural network model and an output target of the teacher neural network model;
performing a backward pass of the teacher neural network model based on the first loss and the second loss;
computing an input gradient through the backward pass; and
adjusting the input sample based on the input gradient.

20. The apparatus of claim 18, wherein the one or more measured statistics comprises a per-channel mean or a per-channels standard deviation of the activations generated at the batch normalization layer during the forward pass.
